(19) United States
(12) Patent Application Publication
(10) Pub. No.: US 2012/0048322 A1
(43) Pub. Date: Mar. 1, 2012

(54) DEVICE FOR CONVERTING INCIDENT RADIATION INTO ELECTRICAL ENERGY

(76) Inventors: Uttam Ghoshal, Austin, TX (US); Ayan Guha, Austin, TX (US)

(21) Appl. No.: 13/138,964

(22) PCT Filed: Jun. 15, 2010
(86) PCT No.: PCT/US2010/001706

§ 371 Date: Nov. 3, 2011

(51) Int. Cl. H01L 35/02; H01L 35/30

(52) U.S. Cl. 136/201; 136/206

(57) ABSTRACT

In various embodiments of the present invention, a device for converting incident radiation to electrical energy is provided. The device includes a Thermoelectric Generator (TEG) and a Photovoltaic Cell (PV) to convert the incident radiation to electrical energy. The device further includes a first component for focusing the incident radiation to the TEG and the PV. The incident radiation includes light waves of infrared wavelengths, and light waves of the visible light spectrum and Ultraviolet (UV) waves. The TEG converts the heat generated due to the light waves of infrared wavelength into electricity, and the PV converts energy of the light waves of the visible light spectrum and UV waves into electricity.

### BACKGROUND

The present invention relates to devices that convert incident radiation, such as solar radiation, into electrical energy. More specifically, the present invention relates to a device that includes a Photovoltaic cell (PV) and Thermoelectric Generator (TEG) for converting incident radiation into electrical energy.

PVs are devices based on the principle of photovoltaic effect which convert the incident radiation on them into electrical energy. The materials used for making PVs include, but are not limited to Silicon, Gallium Arsenide (GaAs), and Cadmium Telluride (CdTe). From these materials, Silicon is generally preferred because it is cheaper than other materials, such as GaAs and CdTe and the process technology that is used for Silicon is developed. Further, a large spectrum of light waves can be captured using Silicon, as it has a low bandgap. Silicon-based PVs typically operate with visible light waves with wavelength between 350 nanometers (nm) to 1000 nm. The incident photons of the light waves having wavelength greater than about 1000 nm have energy less than that of Silicon band gap value (1.1 eV), and cannot create electron-hole pairs. On the other hand, if the incident photons have energy higher than the band gap value, they create high energy electron-hole pairs. However, the excess carrier energy is converted into heat when the carriers are transported across the junction and results in increased temperature that substantially affects the performance of the PVs.

In addition, when PVs operate with light waves of wavelengths higher than that of the visible light spectrum, the efficiency of conversion of energy from the incident radiation into electrical energy is low (<20%). The efficiency of converting incident radiation may be increased by combining PVs and TEGs. TEGs are solid-state devices that convert thermal energy into electrical energy in the presence of a temperature gradient. TEGs can be used to generate electricity from the heat generated by visible light waves and infrared light.

While various combinations of PVs and TEGs have been developed, there is still room for development. Thus a need persists for further contributions in this area of technology.

### SUMMARY

An object of the present invention is to efficiently convert energy from incident radiation into electrical energy.

Another object of the present invention is to facilitate efficient performance of Photovoltaic cells (PVs).

To meet the objectives mentioned above, the present invention provides a device for converting incident radiation into electrical energy. In an embodiment of the present invention, the device includes a Thermoelectric Generator (TEG) and one or more Photovoltaic cells (PVs). The device further includes a first component for concentrating (e.g. by focusing) the incident radiation onto a second component, which is a cold mirror in an embodiment of the present invention. The second component splits the incident radiation in a manner such that the TEG is provided with radiation of infrared wavelength and higher wavelengths, and the PVs are provided with radiation of visible spectrum and ultraviolet wavelength. Such an arrangement allows optimum conversion of the incident radiation, with TEG and PV efficiently converting the low energy and high energy segments of the same spectrum respectively.

In another embodiment of the present invention, a method for generating electrical energy from incident radiation is provided.

### BRIEF DESCRIPTION OF THE DRAWINGS

The preferred embodiments of the present invention will hereinafter be described in conjunction with the appended drawings that are provided to illustrate, and not to limit the invention, wherein like designations denote like elements, and in which:

FIG. 1 illustrates a cross-sectional view of a device for converting incident radiation into electrical energy, in accordance with an embodiment of the invention;

FIG. 2 illustrates a cross-sectional view of a device for converting incident radiation into electrical energy, in accordance with another embodiment of the invention;

FIG. 3 illustrates a cross-sectional view of a device for converting incident radiation into electrical energy, in accordance with yet another embodiment of the invention;

FIG. 4 illustrates a cross-sectional view of a device for converting incident radiation into electrical energy, in accordance with still another embodiment of the invention; and

FIG. 5 illustrates a cross-sectional view of a device for converting incident radiation into electrical energy, in accordance with still another embodiment of the invention.

### DETAILED DESCRIPTION OF THE INVENTION

Before describing the embodiments in detail, in accordance with the present invention, it should be observed that these embodiments reside primarily in the apparatus for conversion of energy from incident radiation into electrical energy. Accordingly, the system components have been represented to show only those specific details that are pertinent for an understanding of the embodiments of the present invention, and not the details that will be apparent to those with ordinary skill in the art.

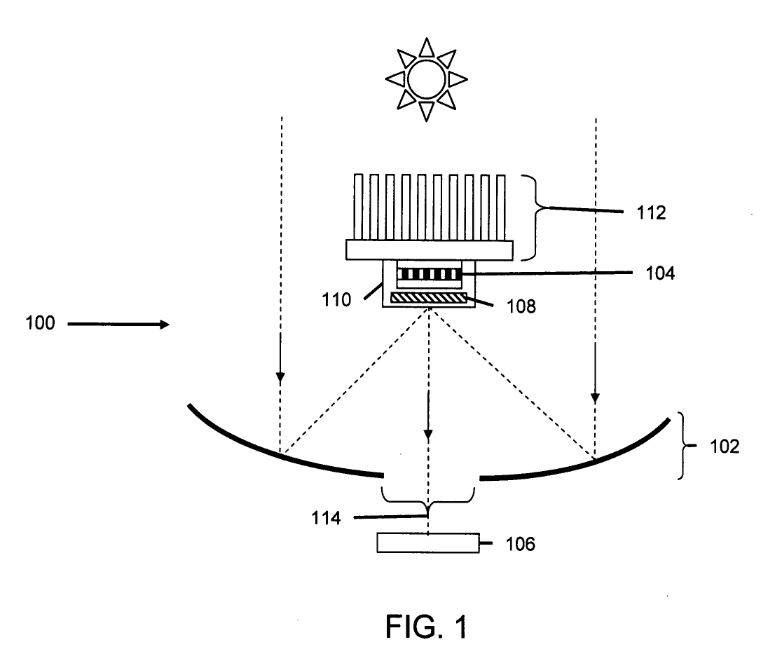

FIG. 1 illustrates a cross-sectional view of a device 100 for converting incident radiation into electrical energy, in accordance with an embodiment of the invention.

Device 100 includes a first component 102, a Thermoelectric Generator (TEG) 104, and a Photovoltaic Cell (PV) 106. First component 102 is placed between TEG 104 and PV 106 in such a way that it focuses the incident radiation on one side of TEG 104. TEGs are solid-state devices which operate on the principle of Seebeck effect. According to the principle, electricity is generated when a temperature gradient is applied across semiconductor materials of these devices. Photovoltaics are devices based on the principle of photovoltaic effect which convert the radiation incident on them into electrical energy.

First component 102 receives incident radiation, which includes light waves of different wavelengths, and concentrates the incident radiation to a smaller region referred to as the focus. Typically, the incident radiation is sunlight which includes light waves of different wavelengths, such as Ultraviolet (UV) radiation and Infrared (IR) radiation.

TEG 104 absorbs the light waves of higher wavelengths, including the light waves of Infrared Radiation (IR) and reflects the light waves of lower wavelengths, including the light waves of visible light spectrum and Ultraviolet radiation (UV). The heat generated due to the absorption of IR helps in creating a temperature gradient across TEG 104, which is used for generating electricity. The light waves that are reflected from TEG 104 are focused at PV 106, which generates electricity from these light waves based on the principle of photovoltaic effect.

In an embodiment of the invention, first component 102 is one of a concave metal mirror, a parabolic reflector and a semi-cylindrical-shaped metal mirror. Further, first component 102, is made from one of tin, molybdenum, aluminum, steel and copper. In another embodiment of the invention, first component 102 is a cold mirror, wherein first component 102 transmits the light waves of infrared wavelength to TEG 104 and reflects the light waves of visible light spectrum and ultraviolet wavelength to PV 106.

The light waves that converge at the focus of first component 102 may be used as a source of heat for creating a temperature gradient across TEG 104. The incident radiation is focused at a hot side of TEG 104 by placing TEG 104 at the focal point of first component 102 for creating the temperature gradient. The hot side of TEG 104 is the side which absorbs heat generated using the incident radiation and dissipates it to the other side, which is referred to as a cold side of TEG 104. TEG 104 can be heated up to substantially high temperatures in the range of about 500 degree Celsius to about 700 degree Celsius by focusing the incident radiation through first component 102. While the hot side of TEG 104 is heated to high temperatures, the other parts of TEG 104 are insulated to prevent heat leakage to the ambient. In one embodiment, TEG 104 is encased in glass or aerogel based on, but not limited to one or more of, silica, titania and alumina (shown as 110 in FIG. 1). This ensures most of the heat passes through TEG 104, instead of leaking to the ambient.

In an embodiment of the invention, a cold mirror 108 is present at the hot side of TEG 104 for transmitting the light waves of the infrared wavelengths. Cold mirrors are specialized dielectric mirrors which efficiently transmit light waves of the infrared wavelengths while reflecting light waves of wavelengths less than that of infrared wavelengths, such as light waves of the visible light spectrum and UV waves. Therefore, the light waves of the infrared wavelengths are transmitted to the hot side of TEG 104. Further, in accordance with the embodiment, cold mirror 108 is enclosed by a transparent insulator 110 that prevents heat generated due to the concentration of light waves of the infrared wavelengths from escaping to the ambient environment.

The hot side of TEG 104 absorbs the heat generated and dissipates it to the cold side of TEG 104, which further dissipates the heat to a heat sink 112 for controlling the temperature of the cold side of TEG 104. Heat sinks are devices that absorb heat from one object, and dissipate heat to another object using thermal contact. These devices operate by efficiently transferring heat from a first object at a relatively high temperature to a second object at a lower temperature. The second object may be an object with high heat capacity, such as air or water. In accordance with the embodiment, heat sink 112 is exposed to the ambient environment.

In another embodiment of the invention, cold mirror 108 is replaced with a tungsten net (not shown in FIG. 1). In this embodiment, the tungsten net is attached to the hot side of TEG 104. The tungsten net also enables absorption of the light waves of the infrared wavelengths and reflection of the light waves of the visible light spectrum and UV waves. In an embodiment of the present invention, the tungsten net is a photonic crystal filter.

The temperature gradient between the hot side and cold side of TEG 104 created due to the incident radiation helps in generating electricity. The efficacy with which the incident radiation is converted into electrical energy depends on the temperature difference across TEG 104. Typically, this efficacy is referred to as Coefficient of Performance (COP) and is calculated based on the electrical energy generated using the incident radiation and the temperature of the hot side and cold side of TEG 104. COP is the ratio of electrical power generated to the heat flowing into the hot side of the TEG 104. Further, COP can be calculated using the following equation:

COP=ε×(Th−Tc)÷Th (1)

Where, ε denotes the thermodynamic efficiency of the TEG, Th denotes the temperature of the hot side of TEG 104, and Tc denotes the temperature of the cold side of TEG 104. For example, when Th=773K (500° C.), Tc=323K (50° C.) and ε=0.25, then COP is 0.15.

The light waves reflected from TEG 104, including visible and UV wavelengths, are transmitted to PV 106 through an opening 114 in first component 102. In an embodiment of the invention, PV 106 is made of silicon, which may convert energies slightly greater than its bandgap (1.1 eV, wavelength<1100 nm). In another embodiment of the invention, PV 106 is made of Gallium Arsenide (GaAs). In yet another embodiment of the invention, PV 106 is made of Cadmium Telluride (CdTe) or Copper-Indium-Germanium-Selenide (CIGS) or other semiconductor.

Typically, the efficacy of conversion of energy of the incident radiation into electrical energy for PV 106 made of silicon is about 20 percent. In an embodiment of the present invention, the efficacy of the conversion is substantially improved because TEG 104 is also used for generating electricity along with PV 106.

In an embodiment of the present invention, PV 106 operates at 20% efficiency and TEG 104 operates at 15% efficiency, thereby increasing the system efficiency to 35%.

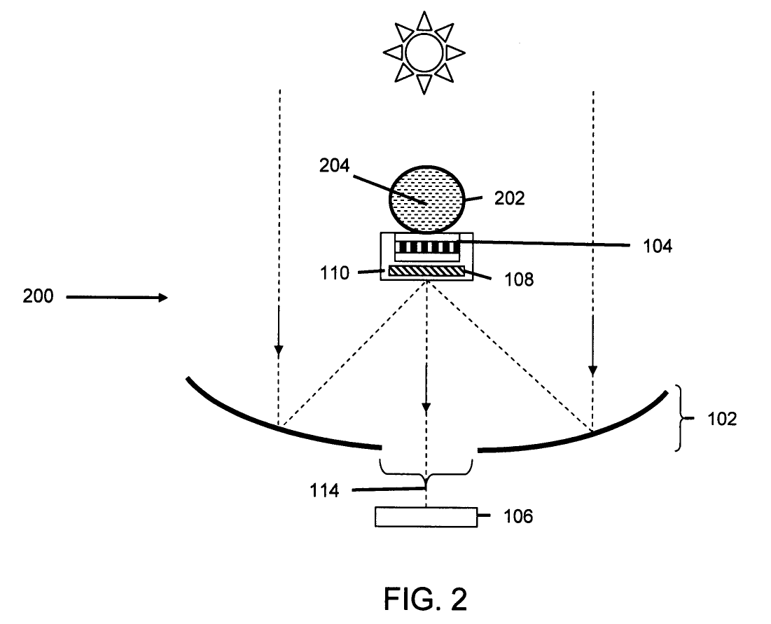

FIG. 2 illustrates a cross-sectional view of a device 200 for converting incident radiation into electrical energy, in accordance with another embodiment of the present invention. Device 200 includes first component 102, TEG 104, and PV 106, as described in reference with FIG. 1.

In accordance with this embodiment, there is a first varied arrangement for controlling the temperature of the cold side of TEG 104. The first varied arrangement includes a first body 202 at the cold side of TEG 104. First body 202 helps in controlling the temperature of the cold side by absorbing heat from the cold side of TEG 104 and dissipating it into a fluid 204 contained within first body 202. Examples of fluid 204 include, but are not limited to, water, ethylene glycol, propylene glycol, and liquid alloys of Ga, In and Bi.

In an embodiment of the invention, first body 202 is a pipe or a channel through which fluid 204 flows. Further, fluid 204 flows in first body 202 in a fluid loop, absorbing heat from TEG 104 and rejecting it to the ambient at a different portion of the loop. Thus, the fluid loop controls the temperature of the cold side of TEG 104. In another embodiment of the invention, first body 202 is a thermal capacitor, such as a water reservoir and a Phase Change Material (PCM). Examples of PCM include, but are not limited to, salt hydrates, fatty acids, esters, and paraffins.

This embodiment of the invention is useful for solar thermal systems that are specifically intended for collecting heat. More specifically, it is applicable for the solar thermal systems that are intended for heating fluids, such as water, ethylene glycol, and propylene glycol. These systems are designed for heating fluids by using the heat absorbed from sunlight. Examples of solar thermal systems include, but are not limited to, solar parabolic, solar trough, and solar towers. When these systems are used for heating fluids, extra cost is incurred in providing first body 202, which can be offset by utilizing first body 202 to control the temperature of the cold side of TEG 104.

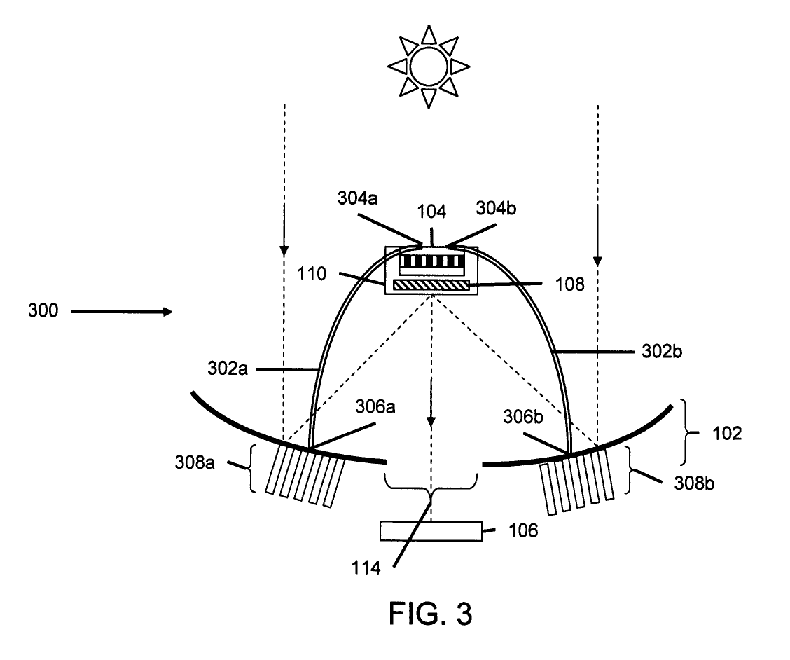

FIG. 3 illustrates a cross-sectional view of a device 300 for converting incident radiation into electrical energy, in accordance with yet another embodiment of the invention. Device 300 includes first component 102, TEG 104, and PV 106, as described in reference with FIG. 1 and FIG. 2.

In accordance with this embodiment, there is a second varied arrangement for controlling the temperature of the cold side of TEG 104. The second varied arrangement includes heat pipes 302a and 302b. Heat pipes are heat transfer mechanisms that transport heat from first ends 304a and 304b at a high temperature to second ends 306a and 306b at a low temperature.

Typically, heat pipes are sealed pipes made of a metal with high thermal conductivity, such as copper and aluminum. These pipes further include fluids, generally referred to as working fluids, for transferring heat from first ends 304a and 304b to second ends 306a and 306b. Examples of working fluids include, but are not limited to, water, ethanol, and ammonia. At first ends 304a and 304b, the fluids absorb heat and evaporate to a gaseous state and move to second ends 306a and 306b, where they condense into a liquid state. The heat pipes may include a wick structure, which applies a capillary pressure on the fluids in the liquid state. Typically, the wick structure is made of a sintered metal powder, or is a series of grooves parallel to the axis of the heat pipe, for exerting capillary pressure on the fluids. Further, second ends 306a and 306b may be thermally connected to heat sinks 308a and 308b through 102 to maintain the temperature of second ends 306a and 306b. In addition, heat sinks 308a and 308b help in the condensation of the fluids at second ends 306a and 306b. In an embodiment of the invention, heat pipes 302a and 302b are sintered heat pipes.

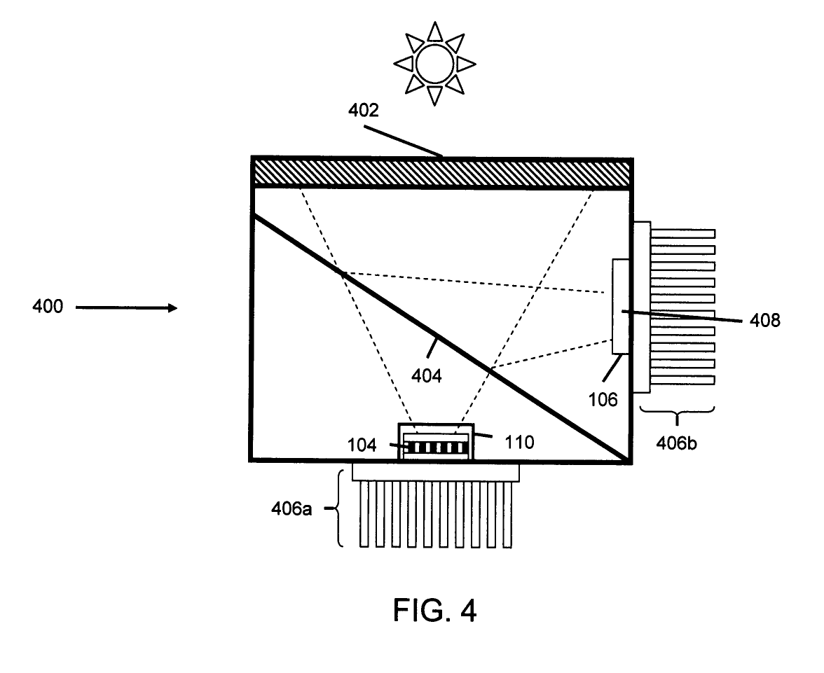

FIG. 4 illustrates a cross-sectional view of a device 400 for converting incident radiation into electrical energy, in accordance with yet another embodiment of the invention. Device 400 includes TEG 104 and PV 106, as described in reference with FIG. 1, FIG. 2 and FIG. 3.

Device 400 includes TEG 104, PV 106, a lens 402, and a second cold mirror 404. Incident radiation is focused on TEG 104 using lens 402. In an embodiment of the invention, lens 402 is a Fresnel lens. A Fresnel lens is a lens with large aperture, short focal length, and substantially lower weight and volume of material than conventional lenses. Fresnel lenses are considerably thinner and cheaper than conventional lenses, and thus, are much easier to manufacture.

Lens 402 is used for focusing the incident radiation on the hot side of TEG 104. Second cold mirror 404 is used for optically splitting the incident radiation into light waves of the infrared wavelengths and light waves of the visible light spectrum and UV waves. Second cold mirror 404 is considered similar in function to cold mirror 108, in accordance with an embodiment of the present invention, in that it allows infrared radiation to be incident on TEG 104 while reflecting UV waves and light waves of the visible light spectrum to PV 106. Further, second cold mirror 404 is placed in between lens 402, TEG 104, and PV 106. Second cold mirror 404 is placed in a manner that it transmits the light waves of the infrared wavelengths to the hot side of TEG 104 and reflects the light waves of the visible light spectrum and UV waves to PV 106. There is a heat sink 406a at the cold side of TEG 104 and a heat sink 406b at a first side 408 of PV 106. Heat sink 406a is provided for controlling the temperature of the cold side of TEG 104. Heat sink 406b is provided at first side 408 to prevent damage to PV 106 due to the heat by controlling the temperature of PV 106.

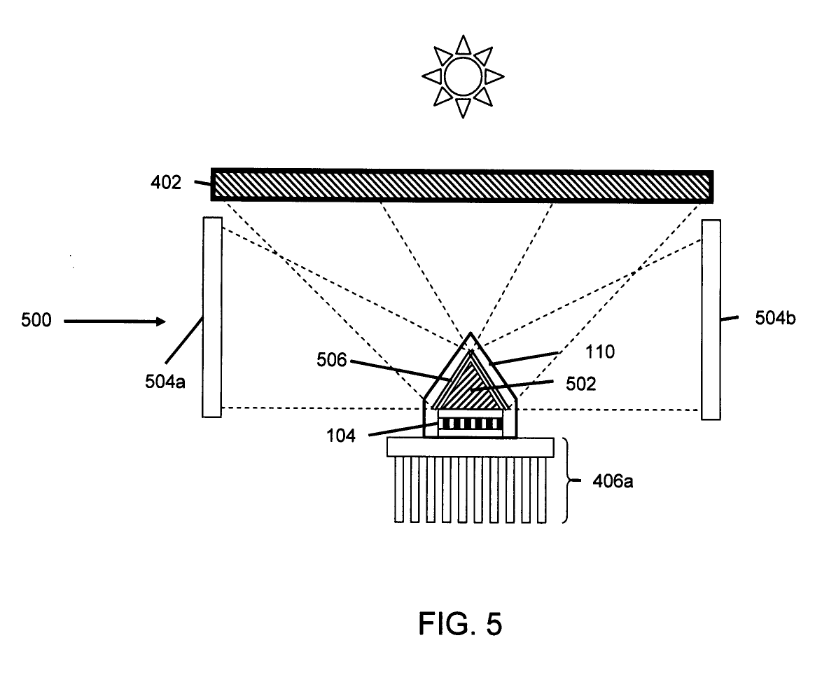

FIG. 5 illustrates a cross-sectional view of a device 500 for converting incident radiation into electrical energy, in accordance with yet another embodiment of the invention. Device 500 includes TEG 104 and lens 402 as described in reference with FIG. 4. Device 500 further includes a third cold mirror 502 and PVs 504a and 504b.

In accordance with this embodiment of the invention, there is an alternative arrangement for splitting the light waves into light waves of infrared wavelengths and light waves of the visible light spectrum and UV waves. In this case, third cold mirror 502 is placed at the hot side of TEG 104. Third cold mirror 502 may be triangular in shape to transmit the light waves of the infrared wavelengths to the hot side of TEG 104 and reflect the light waves of the visible light spectrum and UV waves to PVs 504a and 504b. Third cold mirror 502 is considered similar in function to cold mirror 108, in accordance with an embodiment of the present invention, in that it allows infrared radiation to be incident on TEG 104 while reflecting UV waves and light waves of the visible light spectrum to PVs 504a and 504b, in accordance with an embodiment of the invention. In an embodiment of the invention, a thermally insulating layer 506 is attached to third cold mirror 502 to prevent leakage of heat from the hot side of TEG 104 to the ambient environment. The distance of PVs 504a and 504b may be adjusted based on the material from which PVs 504a and 504b have been made.

The device for converting incident radiation into electrical energy has several advantages. In various embodiments of the present invention, the PVs are exposed primarily to the light waves of the visible light spectrum and UV waves. This helps in preventing damage to the PVs caused by the heat generated due to the light waves of the infrared wavelengths. Further, the PVs can be made of various materials, such as silicon, GaAs, and CdTe, to achieve a desired level of efficiency. In addition, TEGs are used for generating electrical energy from the heat generated due to the light waves of the infrared wavelengths. The arrangements described in various embodiments of the invention facilitate achieving a substantially high efficiency of converting the incident radiation into electrical energy. In various embodiments of the invention, the device may be made of different components and materials. This improves the cost effectiveness of the device.

While the preferred embodiments of the invention have been illustrated and described, it will be clear that the invention is not limited to these embodiments only. Numerous modifications, changes, variations, substitutions, and equivalents will be apparent to those skilled in the art without departing from the spirit and scope of the invention.

What is claimed is:

1. A device for generating electrical energy from incident radiation, the device comprising:
a first component configured to focus the incident radiation;
a second component positioned to receive the incident radiation from the first component, the second component being configured to split the incident radiation into a radiation of infrared wavelength and a radiation of visible spectrum and ultraviolet wavelength;
a thermoelectric generator positioned to receive the radiation of infrared wavelength from the second component, the thermoelectric generator being configured to convert energy of the radiation of infrared wavelength into electrical energy; and
one or more photovoltaic cells positioned to receive the radiation of visible spectrum and ultraviolet wavelength from the second component, the one or more photovoltaic cells being configured to convert energy of the radiation of the visible spectrum and ultraviolet wavelength into electrical energy.

2. The device according to claim 1, wherein the incident radiation is sunlight.

3. The device according to claim 1, wherein the first component is a metal mirror or a parabolic reflector.

4. The device according to claim 1, wherein the first component is a lens.

5. The device according to claim 1, wherein the first component is a Fresnel lens.

6. The device according to claim 1, wherein the second component is a cold mirror.

7. The device according to claim 1, wherein the second component is a tungsten net.

8. The device according to claim 7, wherein the tungsten net is a photonic crystal filter.

9. The device according to claim 1, wherein the second component is triangular in shape to transmit the radiation of infrared wavelength, and reflect the radiation of visible spectrum and ultraviolet wavelength to two photovoltaic cells.

10. The device according to claim 1, wherein the second component is enclosed in a transparent insulator to prevent loss of energy of the incident radiation to the ambient.

11. The device according to claim 1, wherein the second component is enclosed in a transparent aerogel to prevent loss of energy of the incident radiation to the ambient.

12. The device according to claim 1, wherein the device further comprises a heat sink thermally connected to a cold side of the thermoelectric generator to dissipate heat.

13. The device according to claim 1, wherein the device further comprises heat pipes thermally connected to a cold side of the thermoelectric generator to dissipate heat.

14. The device according to claim 1, wherein the device further comprises a first body configured to control the temperature of a cold side of the thermoelectric generator by absorbing heat from the cold side.

15. The device according to claim 14, wherein the first body comprises one or more of a phase change material, water, ethylene glycol, propylene glycol, and liquid alloys of Ga, In and Bi.

16. The device according to claim 1, wherein the second component splits the incident radiation by transmitting the radiation of infrared wavelength, and reflecting the radiation of visible spectrum and ultraviolet wavelength.

17. A method for generating electrical energy from incident radiation, the method comprising the steps of:
splitting the incident radiation into a radiation of infrared wavelength and a radiation of visible spectrum and ultraviolet wavelength;
converting energy of the radiation of infrared wavelength into electrical energy using a thermoelectric generator; and
converting energy of the radiation of visible spectrum and ultraviolet wavelength into electrical energy using one or more photovoltaic cells.

18. The method of claim 17, wherein the incident radiation is sunlight.

19. The method of claim 17 further comprising a step of focusing the incident radiation to a focal point before splitting the incident radiation.

20. The method of claim 17, wherein the step of splitting the incident radiation comprises a step of passing the incident radiation through a second component, wherein the second component transmits the radiation of infrared wavelength and reflects the radiation of visible spectrum and ultraviolet wavelength.

21. The method of claim 20, wherein the second component is selected from a metal mirror, a parabolic reflector, and a lens.

22. The method of claim 17 further comprising a step of dissipating heat at a cold side of the thermoelectric generator through a heat sink.

23. The method of claim 17 further comprising a step of dissipating heat at a cold side of the thermoelectric generator through heat pipes.

24. The method of claim 17 further comprising a step of controlling temperature of a cold side of the thermoelectric generator by one or more of a phase change material, water, ethylene glycol, propylene glycol, and liquid alloys of Ga, In and Bi.
